(19) United States
(12) Patent Application Publication
(10) Pub. No.: US 2026/0075743 A1
(43) Pub. Date: Mar. 12, 2026

(54) ELECTRONIC ASSEMBLY AND CHASSIS ASSEMBLY

(71) Applicants: INVENTEC (PUDONG) TECHNOLOGY CORPORATION, Shanghai (CN); INVENTEC CORPORATION, Taipei City (TW)

(72) Inventors: Wei-Ming WU, Taipei City (TW); Po-Feng CHEN, Taipei City (TW); Chih-Wei CHUANG, Taipei City (TW)

(73) Assignees: INVENTEC (PUDONG) TECHNOLOGY CORPORATION, Shanghai (CN); INVENTEC CORPORATION, Taipei City (TW)

(21) Appl. No.: 19/188,391

(22) Filed: Apr. 24, 2025

(30) Foreign Application Priority Data
Sep. 11, 2024 (CN) 202411274343.7

(51) Int. Cl. H05K 7/14

(52) U.S. Cl. CPC H05K 7/1489

(57) ABSTRACT

An electronic assembly and a chassis, where the electronic assembly includes chassis, riser card assembly and display card assembly. The riser card assembly includes bracket and riser card. The bracket includes main body, handle and first restricting structure. A side of the handle is pivotally connected to the main body. The first restricting structure is located on the handle. The main body is slidably disposed on the chassis. The display card assembly includes tray, display card and second restricting structure. The first restricting structure is located on the tray. The tray is slidably disposed on the chassis. When the tray is assembled to the chassis, the first restricting structure is engaged with the second restricting structure to prevent the handle from being pivoted relative to the main body, thereby preventing the handle from forcing the main body to slide relative to the chassis.

### CROSS-REFERENCE TO RELATED APPLICATIONS

This non-provisional application claims priority under 35 U.S. C. § 119(a) on Patent Application No(s). 202411274343.7 filed in China, on Sep. 11, 2024, the entire contents of which are hereby incorporated by reference.

### BACKGROUND OF THE INVENTION

### Technical Field of the Invention

The invention relates to an electronic assembly and a chassis assembly, more particularly to an electronic assembly including a display card assembly and a riser card assembly and a chassis assembly for a display card and a riser card to be disposed thereon.

### Description of the Related Art

In general, in order to improve space utilization, various electronic components are densely disposed in a server chassis. Thus, the electrical connection between an electronic component with large volume, such as a display card, and a motherboard is usually realized by a riser card.

However, the display card and the riser card are commonly mounted in the server chassis along different directions. Thus, if the riser card is removed from the server chassis before the display card is removed from the server chassis, the connectors on the display card and the riser card that are connected will be damaged.

### SUMMARY OF THE INVENTION

The invention is to provide an electronic assembly and a chassis assembly including restricting structure to prevent the riser card assembly from being removed from the server chassis before the display card is removed from the server chassis, thereby preventing the connectors of the display card assembly and the riser card assembly that are connected from being damaged.

One embodiment of this invention provides an electronic assembly including a chassis, a riser card assembly and a display card assembly. The riser card assembly includes a bracket and a riser card. The bracket includes a main body, a handle and at least one first restricting structure. A side of the handle is pivotally connected to the main body. The at least one first restricting structure is located on a side of the handle located away from the main body. The riser card is disposed on the main body. The main body is slidably disposed on the chassis along a first mounting direction. The display card assembly includes a tray, a display card and at least one second restricting structure. The display card is disposed on the tray and electrically connected to the riser card. The at least one first restricting structure is located on a side of the tray. The tray is slidably disposed on the chassis along a second mounting direction. The first mounting direction is different from the second mounting direction. When the tray is assembled to the chassis, the at least one first restricting structure is engaged with the at least one second restricting structure to prevent the handle from being pivoted relative to the main body, thereby preventing the handle from forcing the main body to slide relative to the chassis.

Another embodiment of this invention provides a chassis assembly configured for a display card and a riser card to be disposed thereon and including a chassis, a bracket, a tray, and at least one second restricting structure. The bracket includes a main body, a handle and at least one first restricting structure. A side of the handle is pivotally connected to the main body. The at least one first restricting structure is located on a side of the handle located away from the main body. The main body is slidably disposed on the chassis along a first mounting direction and configured for the riser card to be disposed thereon. The tray is slidably disposed on the chassis along a second mounting direction and configured for the display card to be disposed thereon. The first mounting direction is different from the second mounting direction. The at least one second restricting structure is disposed on a side of the tray. When the tray is assembled to the chassis, the at least one first restricting structure is engaged with the at least one second restricting structure to prevent the handle from being pivoted relative to the main body, thereby preventing the handle from forcing the main body to slide relative to the chassis.

According to the electronic assembly and the chassis assembly disclosed by above embodiments, when the tray is assembled to the chassis, the first restricting structure is engaged with the second restricting structure to prevent the handle from being pivoted relative to the main body, thereby preventing the handle from forcing the main body to slide relative to the chassis. Therefore, as long as the tray where the display card is disposed is assembled to the chassis, the main body where the riser card is disposed is unable to be removed from the chassis. In this way, the riser card assembly is prevented from being removed from the server chassis before the display card is removed from the server chassis, thereby preventing the connectors of the display card assembly and the riser card assembly that are connected from being damaged.

### BRIEF DESCRIPTION OF THE DRAWINGS

The present invention will become more fully understood from the detailed description given hereinbelow and the accompanying drawings which are given by way of illustration only and thus are not limitative of the present invention and wherein:

FIG. 1 is a perspective view of an electronic assembly according to an embodiment of the invention;

FIG. 2 is an exploded view of the electronic assembly in FIG. 1;

FIG. 3 is a perspective exploded view of a riser card assembly and a display card assembly of the electronic assembly in FIG. 1 that is partially enlarged; and

FIG. 4 is a perspective view showing that the display card assembly of the electronic assembly in FIG. 1 is removed from a chassis.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

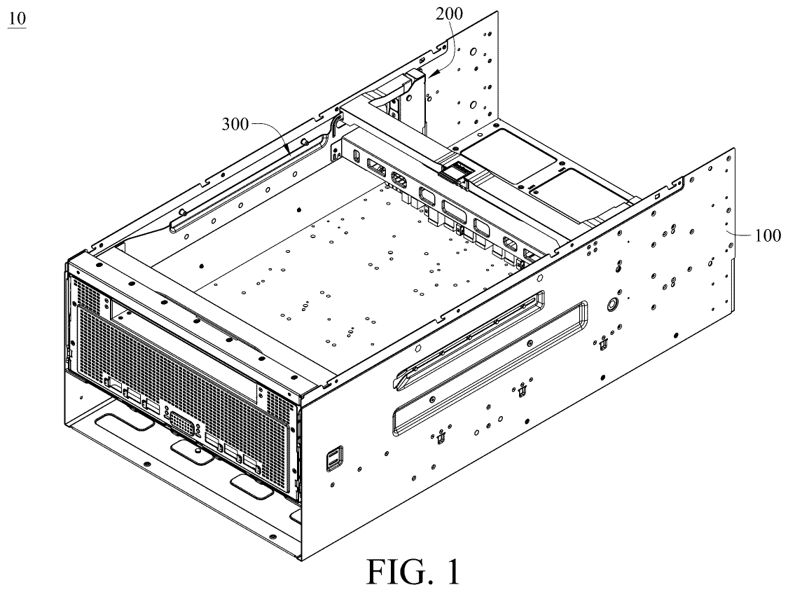

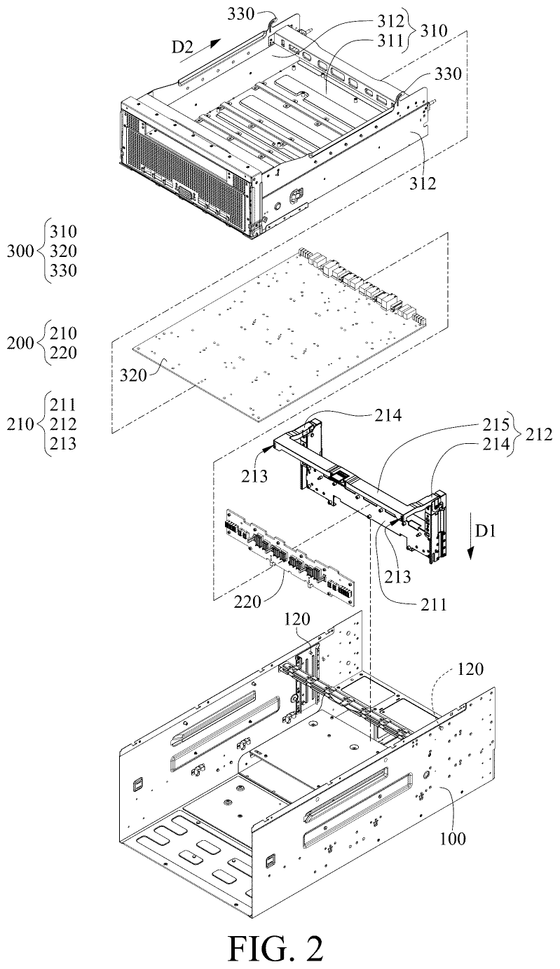

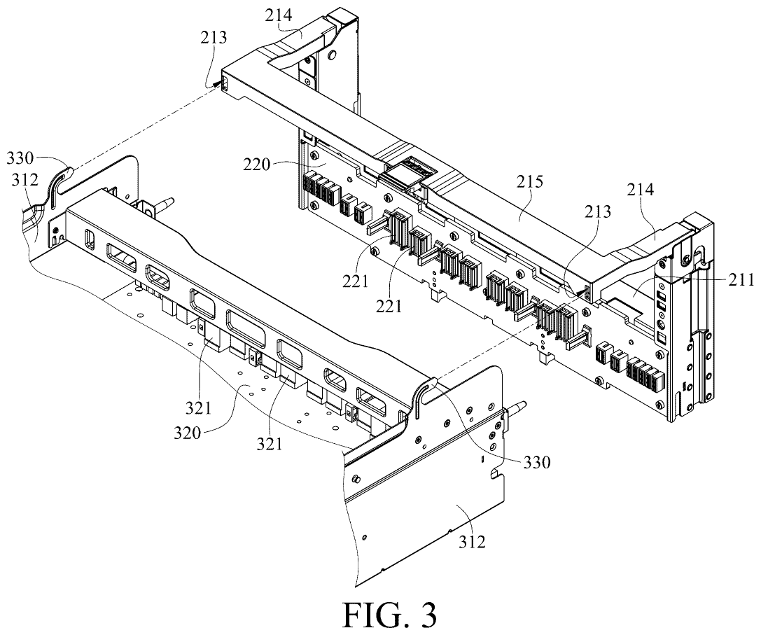

Please refer to FIG. 1 to 3. FIG. 1 is a perspective view of an electronic assembly 10 according to an embodiment of the invention. FIG. 2 is an exploded view of the electronic assembly 10 in FIG. 1. FIG. 3 is a perspective exploded view of a riser card assembly 200 and a display card assembly 300 of the electronic assembly 10 in FIG. 1 that is partially enlarged.

In this embodiment, the electronic assembly 10 includes a chassis 100, the riser card assembly 200 and the display card assembly 300. The chassis 100 is, for example, a server chassis or a server housing. In addition, the display card assembly 300 is, for example, a Graphics Processing Unit (GPU) assembly, but the invention is not limited thereto.

In this embodiment, the riser card assembly 200 includes a bracket 210 and a riser card 220. The bracket 210 includes a main body 211, a handle 212 and two first restricting structures 213. In this embodiment, the handle 212 includes, for example, two mounting parts 214 and a handheld part 215. The handheld part 215 connects the two mounting parts 214. The two mounting parts 214 are pivotally connected two opposite sides of the main body 211, respectively. The two first restricting structures 213 are located on sides of the handheld part 215 located away from the two mounting parts 214, respectively. The riser card 220 is disposed on the main body 211. The main body 211 is slidably disposed on the chassis 100 along a first mounting direction D1.

The display card assembly 300 includes a tray 310, a display card 320 and two second restricting structures 330. The tray 310 is slidably disposed on the chassis 100 along a second mounting direction D2. In this embodiment, the first mounting direction D1 is, for example, perpendicular to the second mounting direction D2. In this embodiment, the tray 310 includes, for example, a bottom plate 311 and two side plates 312. The two side plates 312 are connected to two opposite sides of the bottom plate 311, respectively. The display card 320 is disposed on the bottom plate 311 and electrically connected to the riser card 220. The two second restricting structures 330 protrude, for example, from sides of the two side plates 312 located away from the bottom plate 311, respectively.

Note that the chassis 100, the bracket 210, the tray 310 and the second restricting structures 330 may together be referred as a chassis assembly.

In this embodiment, the first restricting structures 213 and the second restricting structures 330 are engagement slots and engagement hooks matching each other. For example, in this embodiment, the first restricting structures 213 are engagement slots, and the second restricting structures 330 are engagement hooks. However, the disclosure is not limited thereto. In other embodiments, the configuration of the first restricting structures and the configuration of the second restricting structures may be exchanged. That is, the first restricting structures may be engagement hooks, and the second restricting structures may be engagement slots.

Additionally, in this embodiment, the two second restricting structures 330 are in, for example, a curved shape. Also, the two second restricting structures 330 are, for example, integrally formed as a single piece with the two side plates 312, respectively, but the invention is not limited thereto. In other embodiments, the two second restricting structures may be assembled to the two side plates via fasteners, respectively.

Moreover, as shown in FIG. 3, in this embodiment, the display card 320 and the riser card 220 are electrically connected to each other in a board-to-board manner via connectors 321 and 221.

As shown in FIGS. 1 and 3, when the tray 310 is assembled to the chassis 100, the two first restricting structures 213 are respectively engaged with the two second restricting structures 330 to prevent the handle 212 from being pivoted relative to the main body 211, thereby preventing the handle 212 from forcing the main body 211 to slide relative to the chassis 100.

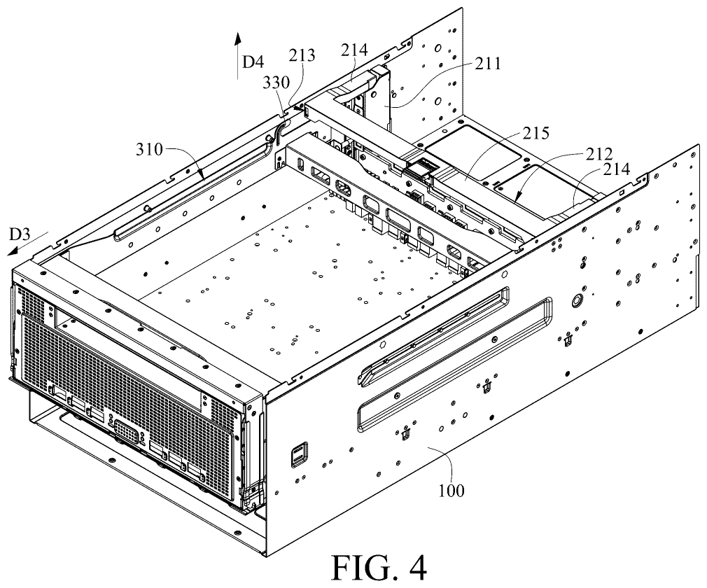

Please refer to FIGS. 2 and 4. FIG. 4 is a perspective view showing that the display card assembly 300 of the electronic assembly 10 in FIG. 1 is removed from the chassis 100. When the tray 310 is removed from the chassis 100 along a first removing direction D3 opposite to the second mounting direction D2, the first restricting structures 213 are detached from the second restricting structures 330. Thus, the handheld part 215 is allowed to force the two mounting parts 214 to be pivoted relative to the main body 211. In this way, with the cooperation of the handle 212 and two pins 120 of the chassis 100, the main body 211 is removed from the chassis 100 by sliding relative to the chassis 100 along a second removing direction D4 opposite to the first mounting direction D1.

According to the electronic assembly and the chassis assembly disclosed by above embodiments, when the tray is assembled to the chassis, the first restricting structure is engaged with the second restricting structure to prevent the handle from being pivoted relative to the main body, thereby preventing the handle from forcing the main body to slide relative to the chassis. Therefore, as long as the tray where the display card is disposed is assembled to the chassis, the main body where the riser card is disposed is unable to be removed from the chassis. In this way, the riser card assembly is prevented from being removed from the server chassis before the display card is removed from the server chassis, thereby preventing the connectors of the display card assembly and the riser card assembly that are connected from being damaged.

The electronic assembly and the chassis assembly provided by this embodiment may be applied in, for example, a server host. The server host may apply Artificial Intelligence (AI) computing, Edge Computing, or may be used as a 5G server, a cloud server or a Vehicle-to-everything (V2X) server.

It will be apparent to those skilled in the art that various modifications and variations can be made to the present invention. It is intended that the specification and examples be considered as exemplary embodiments only, with a scope of the invention being indicated by the following claims and their equivalents.

What is claimed is:

1. An electronic assembly, comprising:
a chassis;
a riser card assembly, comprising a bracket and a riser card, wherein the bracket comprises a main body, a handle and at least one first restricting structure, a side of the handle is pivotally connected to the main body, the at least one first restricting structure is located on a side of the handle located away from the main body, the riser card is disposed on the main body, and the main body is slidably disposed on the chassis along a first mounting direction; and
a display card assembly, comprising a tray, a display card and at least one second restricting structure, wherein the display card is disposed on the tray and electrically connected to the riser card, the at least one first restricting structure is located on a side of the tray, the tray is slidably disposed on the chassis along a second mounting direction, and the first mounting direction is different from the second mounting direction;
wherein when the tray is assembled to the chassis, the at least one first restricting structure is engaged with the at least one second restricting structure to prevent the handle from being pivoted relative to the main body, thereby preventing the handle from forcing the main body to slide relative to the chassis.

2. The electronic assembly according to claim 1, wherein the at least one first restricting structure and the at least one second restricting structure are an engagement slot and an engagement hook matching each other.

3. The electronic assembly according to claim 2, wherein the tray comprises a bottom plate and two side plates, the two side plates are connected to two opposite sides of the bottom plate, respectively, the display card is disposed on the bottom plate, the at least one second restricting structure protrudes from a side of one of the two side plates located away from the bottom plate.

4. The electronic assembly according to claim 3, wherein the at least one second restricting structure and the one of the two side plates are integrally formed as a single piece

5. The electronic assembly according to claim 3, wherein the at least one second restricting structure is in a curved shape.

6. The electronic assembly according to claim 1, wherein the first mounting direction is perpendicular to the second mounting direction.

7. The electronic assembly according to claim 1, wherein the display card and the riser card are electrically connected in a board-to-board manner.

8. A chassis assembly, configured for a display card and a riser card to be disposed thereon, the chassis assembly comprising:
a chassis;
a bracket, comprising a main body, a handle and at least one first restricting structure, wherein a side of the handle is pivotally connected to the main body, the at least one first restricting structure is located on a side of the handle located away from the main body, and the main body is slidably disposed on the chassis along a first mounting direction and configured for the riser card to be disposed thereon;
a tray, slidably disposed on the chassis along a second mounting direction and configured for the display card to be disposed thereon, wherein the first mounting direction is different from the second mounting direction; and
at least one second restricting structure, disposed on a side of the tray;
wherein when the tray is assembled to the chassis, the at least one first restricting structure is engaged with the at least one second restricting structure to prevent the handle from being pivoted relative to the main body, thereby preventing the handle from forcing the main body to slide relative to the chassis.

9. The chassis assembly according to claim 7, wherein the at least one first restricting structure is an engagement slot, and the at least one second restricting structure is an engagement hook.

10. The chassis assembly according to claim 8, wherein the tray comprises a bottom plate and two side plates, the two side plates are connected to two opposite sides of the bottom plate, respectively, the bottom plate is configured for the display card to be disposed thereon, the at least one second restricting structure protrudes from a side of one of the two side plates located away from the bottom plate.
